(19) United States
(12) Patent Application Publication
(10) Pub. No.: US 2020/0056255 A1
(43) Pub. Date: Feb. 20, 2020

(54) METHOD FOR PRODUCING STEEL SHEETS, STEEL SHEET AND USE THEREOF

(71) Applicant: voestalpine Stahl GmbH, Linz (AT)

(72) Inventors: Markus STÖGMÜLLER, Pasching (AT); Dieter PAESOLD, Neuhofen (AT); Thomas HEBESBERGER, Pasching (AT)

(21) Appl. No.: 16/486,607

(22) PCT Filed: Feb. 16, 2018
(86) PCT No.: PCT/EP2018/053885

§ 371 Date: Aug. 16, 2019

(30) Foreign Application Priority Data
Feb. 17, 2017 (DE) 10 2017 103 299.1
Feb. 17, 2017 (DE) 10 2017 103 303.3
Feb. 17, 2017 (DE) 10 2017 103 308.4

(51) Int. Cl. C21D 8/04; C21D 9/48; C22C 38/06; C22C 38/02; C22C 38/04; C22C 38/12; C22C 38/14; C23C 16/06; B61D 17/04; C21D 8/02

(52) U.S. Cl. CPC C21D 8/0405; C21D 9/48; C22C 38/06; C22C 38/02; C22C 38/04; C21D 8/0478; C22C 38/14; C23C 16/06; B61D 17/04; C21D 8/0205; C22C 38/12

(57) ABSTRACT

A method for producing steel sheets, in particular for body shell sheets of vehicles, in which a steel alloy of a desired composition is melted, poured, and then rolled into sheet form, the steel alloy being an interstitial free steel (IF steel) and after the rolling, the steel sheet being annealed and dressed and then provided with a metallic anti-corrosion coating by means of an electrolytic process or by means of vapor deposition, wherein in order to achieve a low Wsa value with the narrowest possible spread, a niobium content of >0.01% by weight, preferably >0.011% by weight, is added to the alloy of the steel.

### FIELD OF THE INVENTION

The present invention relates to a method for producing steel sheets with an improved visual quality after forming.

### BACKGROUND OF THE INVENTION

In order to further improve the visual appearance of automobiles when painted, it has been discovered that while adjusting the strip topography to improve the paint appearance is indeed important, it is not sufficient. Multiple parameters are important for a good visual appearance of the paint in the production of formed and painted sheets.

An essential index for a good paintability and a good paint appearance is the so-called wave surface arithmetic value (Wsa). The 17 Oct. 2013 article “Novel Sheet Galvanizing Gives Automotive Paint Mirror Finish” [Neuartige Blechverzinkung bringt Automobillack anf Hochglanz] published on www.blechnet.com states that a Wsa value of the sheets below 0.35 μm ensures a good paint appearance. First of all, the article says that a low Wsa value is an indication of a good paint appearance. The article goes on to say that because the Wsa value simultaneously correlates to the average roughness (Ra), this also influences the formability. According to the article, experience has shown that it is important to reduce the Wsa value of the sheets to below 0.35 82 m, whereas in conventional sheets the Wsa does indeed lie above 0.5 μm, and to simultaneously provide enough lubrication pockets for the forming, which is successfully achieved by increasing the so-called peak count.

In this case, the focus is placed on using the skin-pass roll to anticipate the subsequent topography of the sheet as a negative allowance in a manner similar to the one used in printing technology. In order to achieve the above-mentioned Wsa values, new roll textures were produced and in addition, thermal processes in the furnace were improved.

A comparable report has been published by thyssenkrupp Steel Europe at www.besserlackieren.de, which likewise includes a description that the surface finishing of the galvanized sheet makes it possible to achieve a corresponding quality.

EP 0 234 698 B1, for example, has disclosed a method in which a surface roughness with defined raised areas is produced.

Aside from hot-dip galvanization, it is possible to use electrolytic galvanization or also vapor deposition (PVD, CVD, . . . ) for applying a cathodic zinc-based anti-corrosion coating to a steel sheet. Whereas with hot-dip galvanization, the strip is conveyed through a liquid zinc bath (approx. 450° C.), electrolytic galvanization or the application of zinc by means of vapor deposition takes place at lower temperatures (below 100° C. and 300° C., respectively).

If the surfaces of an electrolytic galvanization or vapor-deposited zinc coating are compared to a surface produced with hot-dip galvanization, they are clearly different; in particular, the electrolytic galvanization has a high degree of smoothness, but this can be identified as a micro-roughness with ultra-magnification.

Basically, the production of galvanized steel sheets occurs in such a way that steel is produced from raw iron in the convener and cast in a continuous casting plant, then rolled in a hot strip mill, and then cold-rolled. With electrolytic galvanization processes or the application of zinc by means of vapor deposition, before the application of the zinc coating, an annealing and possibly a dressing takes place, and then the electrolytic galvanization or the application of zinc by means of vapor deposition takes place, it being possible for the application of zinc to be followed by a further coating, for example a phosphatization.

Austrian standard EN10152 has disclosed continuously electrolytically galvanized articles made of low-alloy steel for cold forming.

The steels mentioned therein are all low-alloyed steels

Particularly in the automotive sector, IF and BH steels are used in the body shell.

An IF steel is understood to be an “interstitial free” steel that does not have any interstitially embedded foreign atoms (the low quantities of carbon and nitrogen are completely segregated as carbides and nitrides by means of titanium and/or niobium) and therefore has an outstanding plastic deformability. Such steels are used for deep-drawn components in automotive engineering.

Bake-hardening steels (BH steels) feature a significant increase in the yield strength as part of the paint baking (typically at 170° C. for 20 min) in combination with a very-good deformability. These steels also have a very good dent resistance, which is why these steels are often used for body shell applications.

The object of the invention is to create a method for producing steel sheets made of IF steel in an uncoated state or after an additional electrolytic coating or also a coating applied with a CVD or DVD process, steps are carried out with a metallic coating such as Zn, ZnNi, ZnCr, or another metallic coating that serves as an anti-corrosion coating with which the desired Wsa values in the deformed state arc better achieved and the ranges can be reliably maintained.

The measurement of the Wsa values was performed on Marciniak stretch-drawing specimens with 5% deformation, using SEP1941. but in the rolling direction.

### SUMMARY OF THE INVENTION

According to the invention, it has been determined that just by optimizing the long undulation in the non-deformed state, it is not possible to reliably and definitely keep the Wsa value of body shell components in the deformed state within the desired range of <0.35 μm.

According to the invention, it has been determined that the required long undulation limits in the deformed state can be definitely respected by performing selective steps on the material.

In other words, especially by changing the alloy composition in the IF steels used, it is possible to achieve a more reliable production of body shell materials with reduced long undulation in the deformed state.

Correspondingly, it has been determined according to the invention that an ensured adjustment of reduced long undulation in the deformed state can be achieved particularly in IF steels by adding niobium to the alloy in percentages of −=0.02% by weight. In particular, for example, the steel types DC04 through DC07 can be stabilized with a Wsa value at a level of below 0.30 μm.

When using IF steels, if instead of the usual titanium concept for body shell sheets, a titanium-niobium concept is used, then the Wsa level can be stabilized to an average of 0.29 μm.

It has also turned out to be advantageous that with the addition of Nb to the steel, the heating rates for the recrystallization annealing can be varied within a broad range without influencing the Wsa value in a negative way According to the invention, these heating rates are from 5 to 30 K/s.

The dressing or temper-rolling procedure following the recrystallization annealing is used to adjust the mechanical properties and to selectively influence the surface roughness. In the course of this procedure, both the roughness and the long undulation are transmitted from the roll to the strip.

### BRIEF DESCRIPTION OF THE DRAWINGS

The invention will be explained by way of example based on several drawings. In the drawings:

FIG. 1: shows the comparison of long undulation in dressed IF steel in the uncoated state according to the prior art (through example 48) versus the Wsa values that are improved according to the invention, respectively before and after deformation (starting from example 49);

FIG. 2: shows the relationship between the niobium content in the base material (dressed IF steel) and the measured Wsa values in the deformed state; uncoated;

FIG. 3: shows the comparison of long undulation in dressed IF steel in the uncoated state and in the electrolytically galvanized state after deformation;

FIG. 4: shows the alloy according to the invention in the form of a table;

FIG. 5: is a table showing a preferred alloy range;

FIG. 6: is a table showing a particularly preferred alloy range.

FIG. 7: is a table showing several exemplary embodiments; according to the invention and comparison examples.

### DETAILED DESCRIPTION OF THE PREFERRED EMBODIMENTS

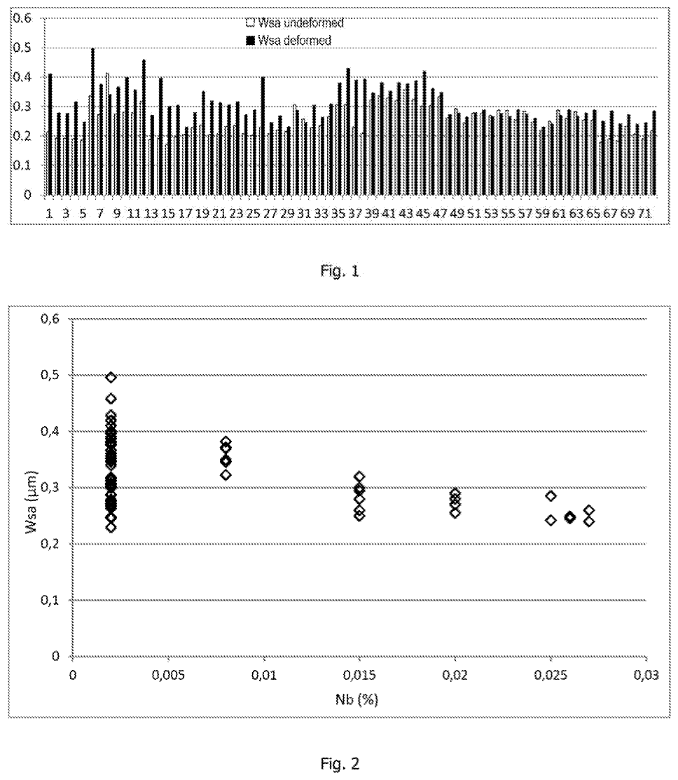

FIG. 1 shows a conventional IF steel, which has been produced and processed according to the prior art (through example 48). The considerable spread of the Wsa values in the course of the deformation is readily apparent. Starting from example 49, die examples are IF steels according to the invention with considerably improved Wsa values and a clearly reduced spread. It is clear that with the invention, the values can be reliably kept approximately at or below 0.30 μm. In this case, the light-colored bars are the Wsa values for the non-deformed state and the black bars are the values for the deformed state.

FIG. 2 clearly shows the relationship between the niobium content in the base material (IF steel) and the measured Wsa values in the dressed, uncoatcd steel in the deformed state. With an increasing Nb content, not only does the Wsa value decrease, but there is also a significant drop in the spread.

According to the invention, a niobium content of >0.02% by weight (200 ppm) is set in the alloy. According to the invention, the niobium content is preferably set to 0.021 to 0.15% by weight, more preferably to 0.021 to 0.10% by weight, and even more preferably to 0.021 to 0.05% by weight. With these values, it is possible to achieve extremely good Wsa values.

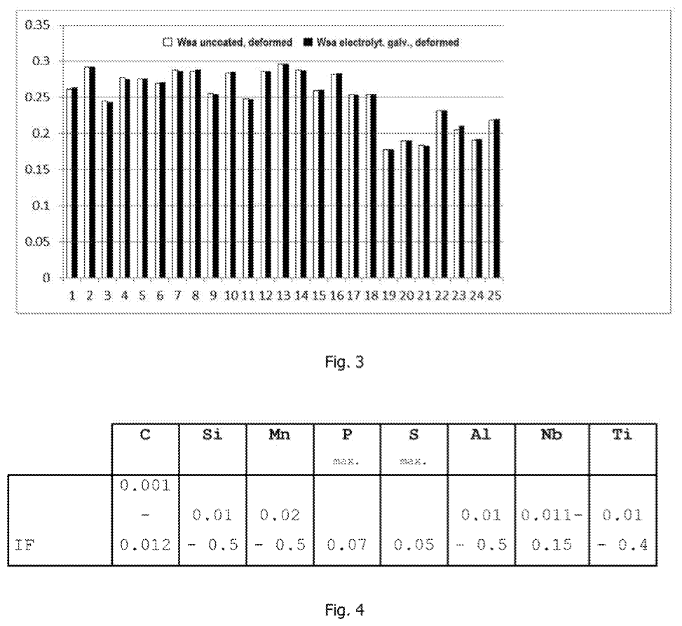

FIG. 3 shows that the change in the Wsa value is almost unaffected by the galvanization process.

Through the use of suitable skin-pass rolls, it is possible to reduce the undulation values of the metallically coated strip in the non-deformed state to a low level. This improvement is no longer present, however, in the deformed state.

The degree of dressing is between 0.5 and 0.75%.

Through the addition of Nb, it was possible to achieve the fact that little or no increase in the Wsa values occurred due to the deformation.

Particularly after the deformation, the IF steels produced according to the invention exhibit considerably better properties than conventional IF steels according to the prior an.

According to the invention, the IF steel can have the alloy composition according to FIG. 4 (all values in percent by weight):

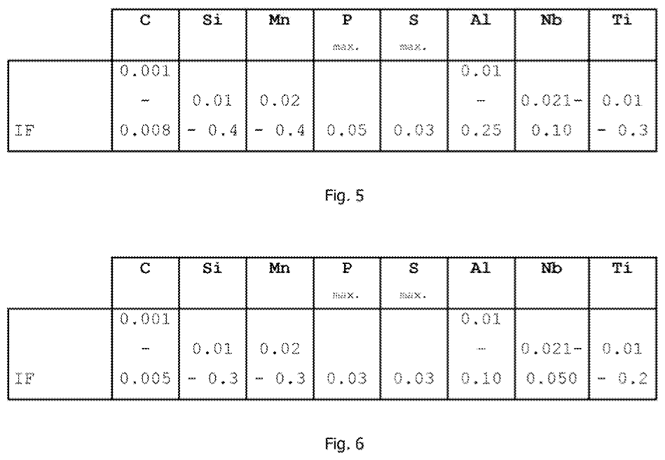

Preferably, the IF steel has the composition according to FIG. 5:

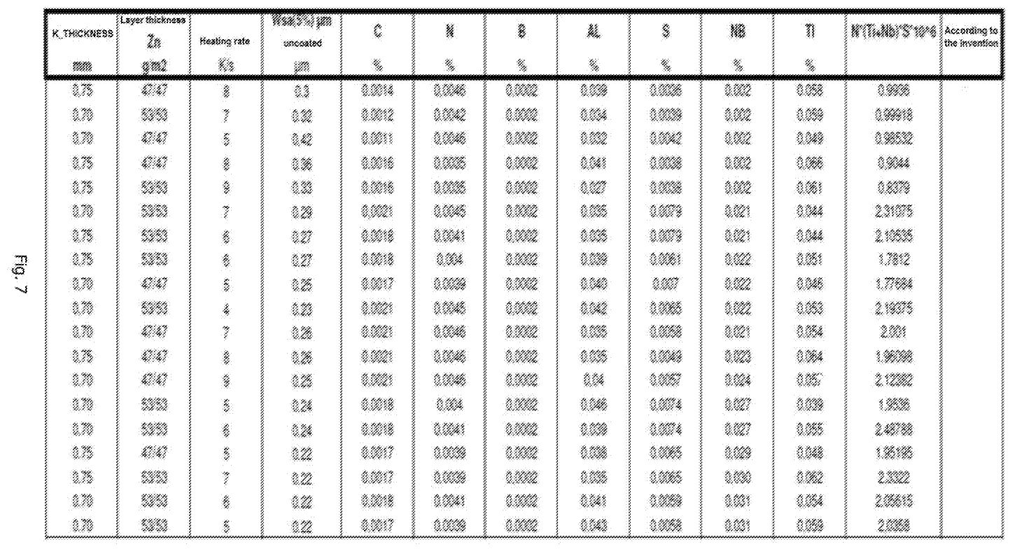

A particularly preferable range of the IF steel is shown in FIG. 6:

The remainder is respectively composed of iron and smelting-dictated impurities.

FIG. 2 shows the corresponding measured relationship in the IF steel, which indicates the Wsa values after deformation plotted over the niobium content In this case, a steady improvement of the Wsa value is apparent as the Nb content increases. This relationship presumably also exists in additions of niobium to the alloy beyond 0.03% by weight. But the ranges according to the invention on the one hand permit a sufficient reduction of the Wsa value and on the other hand, prevent unwanted hardening effects in die base material, which would lead to a reduction in the deformability.

For a low long undulation in the non-deformed state and subsequently in the deformed state, the roll roughness (Ra) for the dressing procedure is set to values of between 1.6 and 3.3 μm in order to be able to maintain the roughness values in the strip that are required by the customer. A further reduction of the Wsa values is possible by reducing roll roughness values, but would require a reduction of the customer's roughness specifications.

All conventional metallic coating materials according to the prior art can be used as the coating material in the electrolytic depositing process. These particularly include, but are not limited to, zinc alloys.

In the invention, it is advantageous that by taking steps within the alloy concept in the steel, it is possible to successfully set the Wsa value to a very low level in a very stable way.

The following examples should demonstrate the positive influence of the niobium content on the formation of the Wsa value level in the formed component (measured in Marciniak specimens with 5% deformation) and should differentiate it from other influences.

In the examples for the coating variants Z listed below, strip speeds and depositing conditions have also been indicated for the sake of completeness. They all lie within the parameters that are customary according to the prior art, but have no significant influence on the Wsa values in the deformed state.

FIG. 1: Examples of Wsa values measured in IF steels according to the prior art (through example 48) and according to the present invention (starting from example 49)

It has turned out that it is advantageous to comply with the following condition.

N*(Ti—Nb)*S*10\hat{ }6

with the proviso that

with pure zinc coatings (Z), the product is >1 and with zinc-magnesium coatings (ZM), the product is >2.

According to the invention, it is thus possible to ensure that rougher deposits are formed. This results in a better deformability without having a negative influence on the strength.

FIG. 2: shows the relationship between the Nb content in the steel and die Wsa values after deformation.

FIG. 3: shows Wsa values in the uncoated steel and after electrolytic galvanization.

1. A method for producing steel sheets, in particular for body shell sheets of vehicles, comprising.
melting an interstitial free steel (IF steel) alloy of a desired composition
adding a niobium content of >0.01% by weight to the steel alloy in order to achieve a low Wsa value with a narrowest possible spread;
pouring the steel alloy, and rolling the steel alloy into sheet form; and
annealing and dressing the steel sheet after the rolling.

2. The method according to claim 1, wherein the IF steel has the following analysis in % by weight:

| | |
|---|---|
| C | 0.001-0.015 |
| Si | 0.01-0.5 |
| Mn | 0.02 to 0.5 |
| P | max. 0.1 |
| S | max. 0.05 |
| Al | 0.01 to 1.0 |
| Nb | 0.011 to 0.15 |
| Ti | 0.01 to 0.4 |

optionally containing one or more of the following elements:
up to max. 100 ppm boron and/or
up to 0.4% by weight vanadium and/or
up to 0.4% by w eight zirconium;
a remainder composed of iron and smelting-dictated impurities.

3. The method according to claim 1, wherein the IF steel has the following analysis in % by weight:

| | |
|---|---|
| C | 0.001 to 0.020 |
| Si | 0.01 to 0.7 |
| Mn | 0.02 to 1.5 |
| P | max. 0.15 |
| S | max. 0.05 |
| Al | 0.015 to 1.0 |
| Nb | 0.02 to 0.15 |
| Ti | 0.01 to 0.2 |

optionally containing one or more of the following elements:
up to max. 100 ppm boron and/or
up to 0.4% by weight vanadium and/or
up to 0.4% by weight zirconium, and or
up to 0.5% by weight hafnium, and/or
up to 0.5% by weight tungsten, and/or
up to 0.5% by weight tantalum;
a remainder composed of iron and smelting-dictated impurities.

4. The method according to claim 1, comprising, after the dressing, providing the steel sheet with a metallic anti-corrosion coating using an electrolytic process or vapor deposition.

5. The method according to claim 4, comprising applying the metallic anti-corrosion coating to the steel sheet electrolytically or using a CVD or PVD process, the wherein the metallic coating is selected from tire group consisting of: zinc-chromium, zinc-nickel, zinc-magnesium, zinc-titanium, zinc-calcium, zinc alloys with zirconium, hafnium, cerium, and mixed metals or metals composed of rare earths

6. The method according to claim 1, comprising using skin-pass rolls with a roughness (Ra) of 1.6 to 3.3 μm.

7. The method according to claim 1, wherein a degree of dressing is between 0.5 and 0.75%.

8. The method according to claim 1, wherein the alloy fulfills to the following condition: N*(Ti—Nb)*S*10\hat{ }6, the product being greater than 1.

9. The method according to claim 1, comprising annealing the steel sheet at a heating rate between 5 K/s and 30 K/s.

10. A steel sheet produced according to the method of claim 2.

11. A method of using the steel sheet according to claim 10, comprising using the steel sheet to form body shell components of motor vehicles and/or buildings.

12. A steel sheet produced according to the method of claim 3.

13. A method of using the steel sheet according to claim 12, comprising using the steel sheet to form body shell components of motor vehicles and or buildings.
